(19) United States
(12) Patent Application Publication
(10) Pub. No.: US 2018/0029614 A1
(43) Pub. Date: Feb. 1, 2018

(54) RAILROAD CAR

(71) Applicant: SIEMENS AKTIENGESELLSCHAFT, MUNICH (DE)

(72) Inventors: PETER MULL, NUERNBERG (DE); IOSSIF TOKMAN, NUERNBERG (DE)

(21) Appl. No.: 15/551,295

(22) PCT Filed: Feb. 12, 2016
(86) PCT No.: PCT/EP2016/053035

§ 371 Date: Aug. 16, 2017

(30) Foreign Application Priority Data
Feb. 19, 2015 (DE) 10 2015 202 991.3

(51) Int. Cl. B61C 17/12; H05K 5/02; H05K 7/20; H05K 1/18; H02B 1/30; B61D 1/00; H05K 5/00

(52) U.S. Cl. CPC B61C 17/12; B61D 1/00; H05K 5/0247; H05K 5/0065; H05K 1/18; H02B 1/30; H05K 7/20418; H05K 5/0217; H05K 2201/10083

(57) ABSTRACT

A railroad car includes a control system. In order to obtain a space-saving configuration of the control system of the railroad car, the control system includes a plurality of functional modules, each having a housing with at least one externally accessible electrical interface and being disposed decentrally with respect to each other.

The invention relates to a railroad car. Railroad cars today are normally equipped with a control system comprising a multiplicity of control elements, in particular a multiplicity of contactors. The individual control elements are used to realize various functions of the control system such as e.g. the control of a safety circuit, a coupling, a car master switch or a fire alarm system.

In existing railroad cars, the control elements of the respective control system are arranged in switchgear cabinets. Such switchgear cabinets are however associated with a number of disadvantages. For example, one disadvantage is that the switchgear cabinets have a large volume and consequently result in a reduction in the usable space of the railroad car, in particular a reduction in the space that can be used for passenger seating. The reduction in the usable space is aggravated further because the switchgear cabinets are not usually adapted in shape to the geometry of a car, and therefore hollow spaces occur in the railroad car between a switchgear cabinet and a car body wall, this having an adverse effect on the usable space.

The object of the invention is to specify a railroad car with a control system, wherein a space-saving arrangement of the control system is possible.

This object is inventively achieved by a railroad car with a control system which comprises a plurality functional modules, wherein said functional modules have a housing with at least one externally accessible electrical interface and are arranged decentrally with respect to each other in each case.

The invention proceeds from the notion that the functional modules can have control elements that were previously arranged in switchgear cabinets. This means that control elements of a switchgear cabinet can be transferred out into the functional modules. In this way, the switchgear cabinet can have smaller dimensions or can even be omitted altogether. Furthermore, the individual functional modules appropriately have smaller dimensions than the switchgear cabinets that were used previously. It is therefore possible to arrange some or all of the functional modules in previously unused spaces, in particular in hollow spaces. Furthermore, a decentralized arrangement of the functional modules makes it possible to use a plurality of such previously unused spaces for the purpose of arranging functional modules is these spaces. Usable space of the railroad car, in particular space that is used for passenger seating, can therefore be increased.

By virtue of the decentral arrangement of the functional modules, it is possible to ensure that the functional modules do not generate their waste heat at a single location, but at a plurality of different locations. In contrast with existing switchgear cabinets, it is consequently possible to dispense with active cooling devices for the functional modules. This in turn allows the functional modules to be operated in an energy-saving manner. The usable space of the railroad car can also be further increased since in particular power supply units for active cooling devices can be omitted, and passive cooling devices can also be of more compact design than active cooling devices. Depending on the design of the functional modules, it is possible in principle to dispense with cooling devices entirely for individual functional modules or for all functional modules.

The invention further proceeds from the notion that the control elements which are transferred out to the functional modules and those car-related elements which are controlled by said control elements must be connected together electrically. For this purpose, the housings of the functional modules each have at least one externally accessible electrical interface. By this means, the functional modules can be electrically connected to one or more car-related elements with little effort during installation. This also allows the functional modules to be replaced, in particular separately, with little effort.

For the purposes of the invention, the control system is configured to receive, send and/or process electrical signals. For the purposes of the invention, the control system is further configured to control one or more components of the railroad car, e.g. one or more electrical circuits. In this context, the term “control” can also include in particular switching one or more components.

In this context, a functional unit can be considered to be a unit of the control system which is configured to realize one or more functions of the control system, in particular by controlling one or more components of the railroad car, e.g. one or more electrical circuits. Each of the functional modules is preferably assigned one or more dedicated functions. In particular, it is possible for the individual functions of the control system to be realized by precisely one of the functional modules in each case.

The individual functional modules appropriately have at least one control element in each case, in particular a control element for a safety circuit, a coupling control, a master switch control, an emergency running control and/or a fire alarm system.

A decentral arrangement of the functional modules with respect to each other can be understood to mean that at least two of the functional modules are so arranged as to be spatially separate from each other, e.g. having a distance of at least 50 cm from each other. Provision is preferably made for at least two of the functional modules to be placed at different locations, in particular in different zones, of the railroad car. One of the functional modules can be arranged in an underfloor zone or an embarkation zone, for example. Another of the functional modules can be arranged in a seating zone, for example. At least two of the functional modules are preferably arranged at different wall elements of the railroad car and/or separated from each other by at least one wall element of the railroad car. Furthermore, the functional modules are preferably not arranged in a shared overall housing.

For the purposes of the invention, the housings of the functional modules are sealed housings. In particular, the housings are preferably so embodied as to be fireproof. The housings can then satisfy the prescribed fire-safety requirements.

An externally accessible interface of a housing can be understood to be an interface which can be accessed from outside the housing. For the purposes of the invention, such an interface is arranged at least partially on an outer side of the housing.

The electrical interface of the respective functional module can be a data interface in particular. The interface can therefore be designed for the purpose of transferring data in particular. For the purposes of the invention, the interfaces of the functional modules are moreover so configured as to establish an electrical connection between an element in the respective housing and an element outside the housing. In this way, it is possible to establish and/or separate an electrical connection between the respective functional module and a further element with little effort.

According to an advantageous embodiment of the invention, each of the functional modules has at least one printed circuit board. The printed circuit board of the respective functional module is appropriately arranged in the housing thereof. For the purposes of the invention, the printed circuit board, also referred to as a circuit board or printed circuit or PCB, is electrically connected to the interface of the respective functional module. Furthermore, the printed circuit board can be designed as a plug-in card in particular. Furthermore, the printed circuit board can comprise electrically conductive conductor tracks.

Provision is advantageously made for a relay unit to be connected, in particular electrically connected, to the printed circuit board. For the purposes of the invention, the relay unit forms a control element of the control system. The relay unit is preferably soldered onto the printed circuit board. Alternatively, the relay unit can be connected to the printed circuit board by other means, e.g. by means of a welded, screw or adhesive connection. The relay unit can comprise one or more relays. If a plurality of relays are present, these are electrically connected together for the purposes of the invention, in particular via the previously mentioned conductor tracks. Furthermore, the relay unit is appropriately electrically connected to the interface of the respective functional module. Moreover, the relay unit can comprise one or more control circuits for control of the relay or relays. The use of relays instead of contactors allows a more compact embodiment of the functional modules, since relays usually have smaller dimensions than contactors.

Alternatively or in addition to the relay unit, at least one other electrical component can be connected to the printed circuit board. In particular, this component can form a control element of the control system. Furthermore, the component can be soldered onto the printed circuit board or otherwise connected to the printed circuit board.

The printed circuit board can also be electrically connected to the interface of the respective functional module by means of a back panel, also referred to as a backplane or bus board. In this type of configuration, the back panel is electrically connected to both the printed circuit board and to the respective interface for the purposes of the invention. In particular, the back panel can be soldered to the interface of the respective functional module. In addition, the back panel can have one or more slots. The printed circuit board can be plugged into one of the these slots, for example.

It is also possible for the printed circuit board to be electrically connected to the interface of the respective functional module by means of at least one cable. For the purposes of the invention, the cable is electrically connected to both the printed circuit board and the respective interface in this case. The cable can have a first plug-type connector. Said first plug-type connector can be plugged into a counterpart of the printed circuit board. The cable can also have a second plug-type connector. The second plug-type connector can likewise be plugged into a counterpart of the respective interface. The back panel and the cable respectively are appropriately arranged in the housing of the respective functional module.

Furthermore, each of the functional modules can have a printed circuit board support unit in its housing. For the purposes of the invention, the printed circuit board support unit of the respective functional module is designed to secure or hold the respective printed circuit boards in place in the housing.

In an advantageous development of the invention, at least one of the functional modules has a plurality printed circuit boards. Moreover, this functional module ideally has at least one dedicated externally accessible electrical interface for each of its printed circuit boards.

Furthermore, the control system of the railroad car can comprise a switchgear cabinet and/or an E-container. One or more control elements can be arranged in the switchgear cabinet or the E-container. Such a control element can be in particular a contactor, a relay or a mechanically selectable switch. Operator devices and/or display devices can also be arranged in the switchgear cabinet or the E-container.

The functional modules are preferably arranged outside the switchgear cabinet or the E-container. Furthermore, at least one of the functional modules can be communicatively connected to at least one of the control elements of the switchgear cabinet or E-container, e.g. via a communication line in each case. For the purposes of the invention, the connection line is designed for the purpose of transferring data, e.g. by means of electrical signals. In particular, all of the functional modules can be communicatively connected via a communication line in each case to at least one of the control elements of the switchgear cabinet or E-container.

In a further preferred embodiment, the housings of at least two functional modules, in particular the housings of all functional modules, have the same dimensions. The housings can be identical in width, depth and/or height. This allows the functional modules to be produced with little effort and/or at little cost.

Provision can be made for at least two and preferably all of the functional modules to be communicatively connected to each other, e.g. via connection lines. These functional modules can be configured to exchange data with each other.

Moreover, provision can be made for at least one of the functional modules to have at least one heat sink, in particular a passive heat sink. For the purposes of the invention, the heat sink is fastened to the housing of the respective functional module, in particular to an outer side of the housing. The heat sink can also comprise a plurality of cooling fins. Furthermore, the functional modules having at least one heat sink may differ in respect of the side of their housing to which the heat sink is fastened.

The individual functional modules can preferably be mounted in any desired location. Therefore at least one of the functional modules can be oriented e.g. horizontally, vertically or obliquely relative to an installation surface, in particular in order to allow a space-saving arrangement of said functional module.

For the purposes of the invention, at least one and preferably each functional module is equipped with a fastening element. The fastening element can be used to fasten the respective functional module to a component of the railroad car, in particular by means of a screw connection. The fastening element can also be designed as an angle bracket, for example. The fastening element is preferably attached to the housing of the respective functional module by means of a screw connection. Alternatively, the fastening element can be attached to the housing by other means.

In an advantageous embodiment of the invention, each of the functional modules is equipped with two fastening elements. The fastening elements preferably have two sections, in particular two plate-like sections. Moreover, the two sections of the respective fastening element can be oriented inter alia perpendicularly or largely perpendicularly relative to each other. With regard to the individual functional modules, the fastening elements can be attached in each case to the same housing side or to different housing sides. Furthermore, at least two of the functional modules may differ in respect of the sides of their housing to which their respective fastening elements are attached.

Furthermore, the housings of the functional modules can be equipped with blind rivet nuts in each case. Moreover, the fastening elements of the respective functional module can be screwed onto the housing thereof using these blind rivet nuts.

The railroad car is preferably intended for passenger transport. For the purposes of the invention, the railroad car is equipped with a plurality of passenger seats. It is further advantageous for at least one of the functional modules to be arranged under, in particular immediately under, at least one of the passenger seats. In this way, a previously unused space under the passenger seat can be used to accommodate one or more functional modules.

The railroad car appropriately has a car body roof. For the purposes of the invention, the railroad car is further equipped with an inner ceiling. At least one of the functional modules is advantageously arranged between the car body roof and the inner ceiling. Therefore a previously unused space between the car body roof and the inner ceiling can be used to accommodate one or more functional modules.

An inner ceiling can be understood to be an element of a paneling. In particular, the inner ceiling can be an element of a paneling which conceals the car body roof. In addition, the inner ceiling can be fastened to the car body roof. Moreover, the inner ceiling can provide an upper limit to the passenger space and/or a locomotive driver space. A passenger space can be considered as that spatial zone of the railroad car which is intended to accommodate one or more passengers. In particular, the passenger space can be a seating zone, an embarkation/debarkation zone, a toilet space and/or a dining car.

Furthermore, the car body roof can have at least one cove. A cove here can be considered to be a curved section of the car body roof. For the purposes of the invention, the cove forms a transition of the car body roof to a car body side wall. The functional module which is arranged between the inner ceiling and the car body roof can be placed inter alia under the cove.

For the purposes of the invention, the railroad car also has an embarkation zone. The embarkation zone appropriately comprises an entry door. An embarkation zone can be considered to be a volume which is adjacent to the entry door and extends between the car body roof and a passenger floor of the railroad car. In a direction which is perpendicular to the longitudinal direction of the car, the volume can be delimited in particular by a car body side wall in which the entry door is arranged and a plane which is parallel to the car body side wall and is situated at a distance of e.g. 1 m from the car body side wall. In a longitudinal direction of the car, the volume can be delimited in particular by two planes which are oriented perpendicularly relative to the longitudinal direction of the car are situated in each case at a distance of e.g. 50 cm from the entry door.

The functional module which is arranged between the inner ceiling and the car body roof can be placed inter alia in the embarkation zone, in particular above the entry door. An arrangement of the last-cited functional module “above the entry door” can be understood in this context to mean that the functional module is situated higher than the entry door. In this type of configuration, the functional module can be laterally offset relative to the entry door.

The railroad car appropriately has a car body floor. One or more of the functional modules can be arranged under the car body floor, in particular in an underframe of the railroad car. It is also useful for the railroad car to have a floorpan. It is further advantageous for at least one of the functional modules to be arranged between the car body floor and the floorpan. A floorpan can be considered to be a container in the shape of a trough, which is arranged under the car body floor in particular.

In addition, the railroad car appropriately has a car body side wall, in particular a car joining wall. For the purposes of the invention, the car body side wall is so oriented as to be essentially or at least sectionally vertical. Moreover, the car body side wall is ideally connected to the car body floor and/or the car body roof. A car joining wall can also be understood to mean a car body side wall of the railroad car through which a vehicle passenger can pass from the railroad car into a further railroad car, in particular a railroad car which is coupled thereto. The car joining wall appropriately has a clear passageway and optionally a door.

In addition, the railroad car can have a side wall inner paneling. A side wall inner paneling can be understood to be an element of a paneling. In particular, the side wall inner paneling can be an element of a paneling which conceals the car body side wall. Moreover, the side wall inner paneling can laterally delimit the passenger space and/or the locomotive driver space. Furthermore, the side wall inner paneling can be fastened to the car body side wall. At least one of the functional modules is preferably arranged between the car body side wall and the side wall inner paneling.

The railroad car can also have a luggage rack. For the purposes of the invention, the luggage rack is arranged next to a car body side wall of the railroad car. Provision can also be made for at least one of the functional modules to be arranged between the luggage rack and the car body side wall.

The railroad car can also have a cabinet. This cabinet can be e.g. a switchgear cabinet, in particular the switchgear cabinet mentioned previously. For the purposes of the invention, the cabinet is arranged next to a car body side wall of the railroad car. At least one of the functional modules is preferably arranged between the cabinet and the car body side wall. The cabinet can also be arranged next to a compartment separating wall of the railroad car. In this case, at least one of the functional modules can be arranged between the cabinet and the compartment separating wall.

The railroad car can also have a further cabinet, which is placed at least partially in the embarkation zone. Provision can also be made for at least one of the functional modules to be arranged in the further cabinet.

The foregoing description of advantageous embodiments of the invention contains numerous features, some of which are specified in combination as multiples in the individual subclaims. However, these features can also be considered individually for the purposes of the invention, and combined to form further appropriate combinations. In particular, these features can be combined with the inventive railroad car, individually or in any suitable combination in each case.

Although certain terms in the description or in the patent claims are used in the singular or in connection with a numeral, the scope of the invention in respect of these terms is not restricted to the singular or the respective numeral. Moreover, the words “a” or “an” do not represent numerals but indefinite articles.

The properties, features and advantages of the invention as described above, and the manner in which these are achieved, become clearer and easier to understand in the context of the following description of the exemplary embodiment of the invention, which is explained in greater detail in connection with the drawings. The exemplary embodiment serves to explain the invention and does not limit the invention to the combinations of features specified therein, or in respect of functional features. Moreover, suitable features of the exemplary embodiment can also be considered explicitly in isolation and combined with any of the claims.

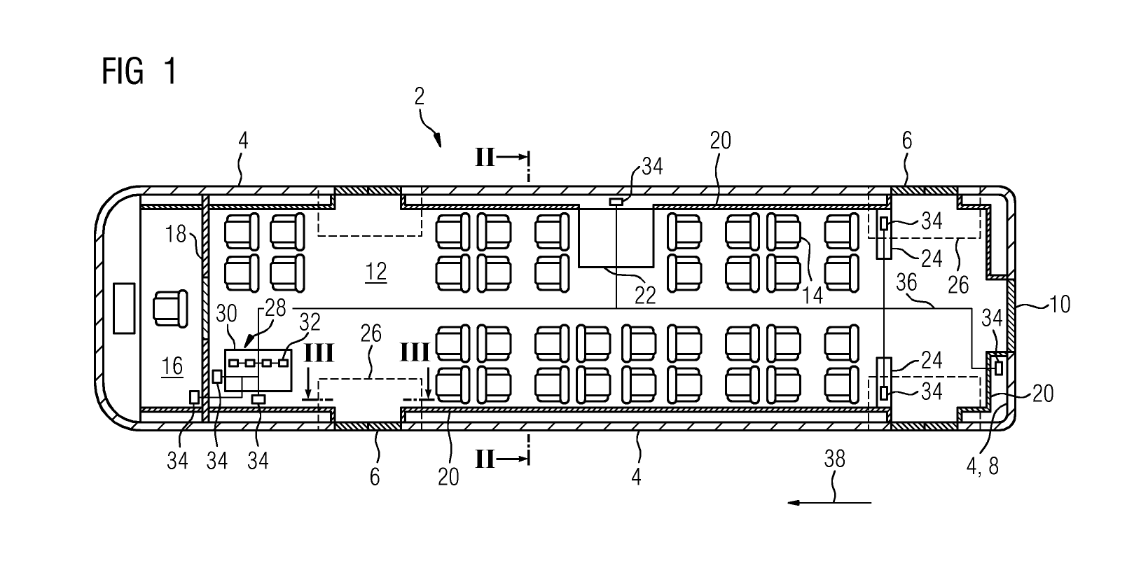

FIG. 1 shows a schematic sectional view of a railroad car with a control system comprising a plurality of functional modules which are arranged decentrally with respect to each other;

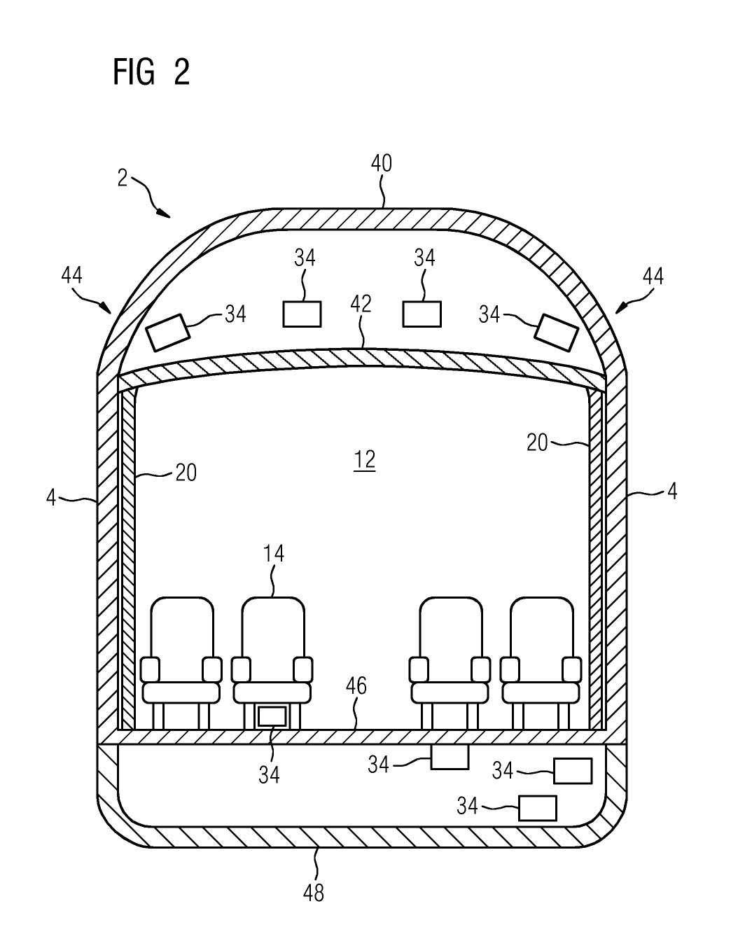

FIG. 2 shows a schematic section of the railroad car along a sectional plane II-II from FIG. 1;

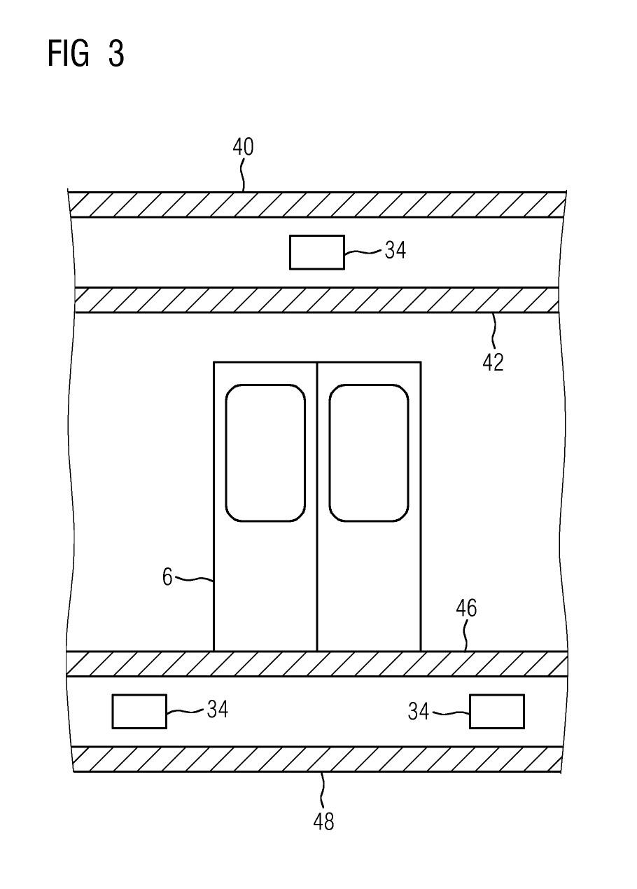

FIG. 3 shows a schematic section of the railroad car along a further sectional plane III-III from FIG. 1;

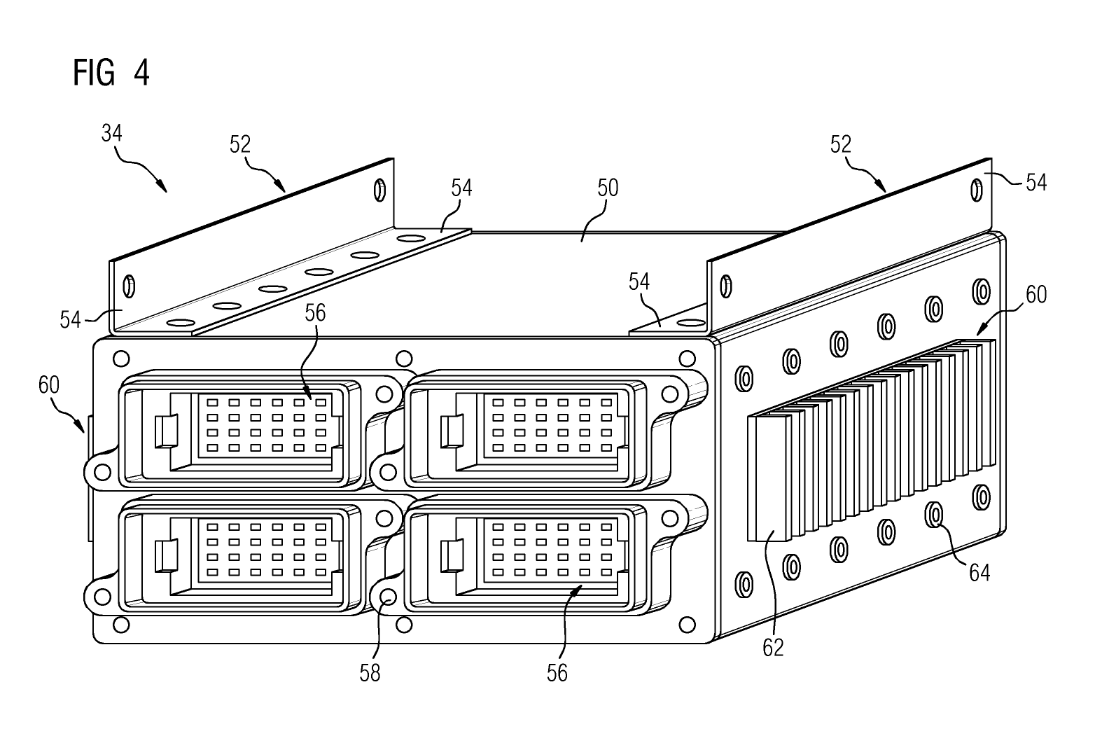

FIG. 4 shows an exemplary embodiment of one of the functional modules of the railroad car in a perspective view;

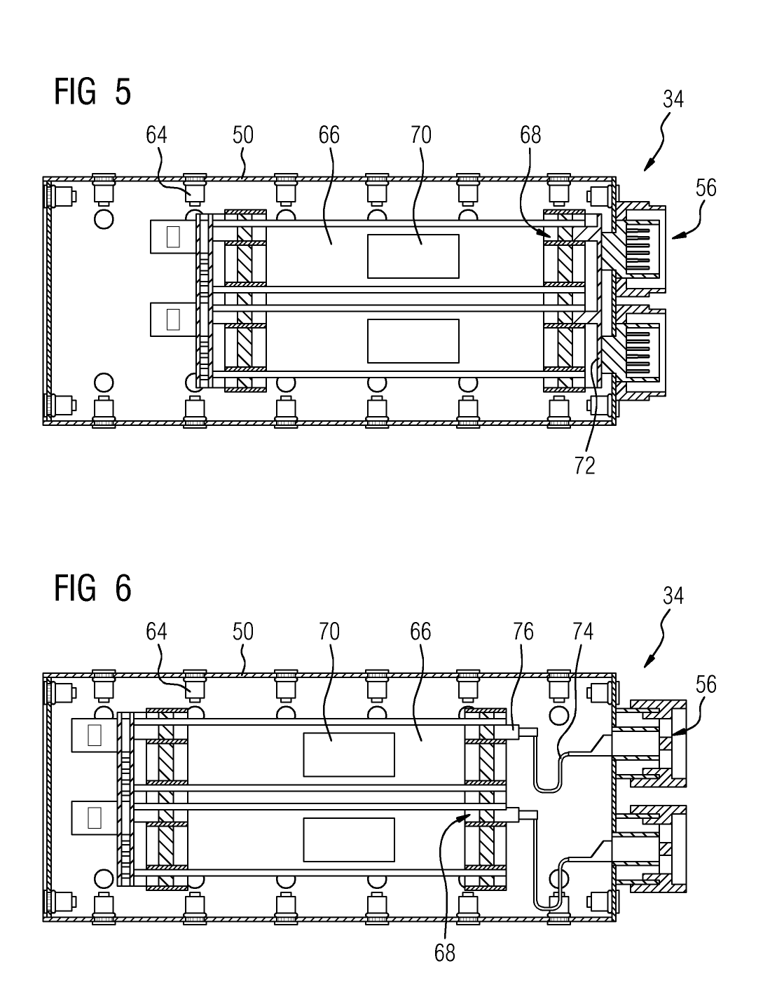

FIG. 5 shows a section through a housing of the functional module from FIG. 4; and

FIG. 6 shows a section through a housing of a further functional module of the railroad car.

FIG. 1 shows a schematic sectional view of a railroad car 2 for passenger transport, illustrated in a top view.

The railroad car 2 has a plurality car body side walls 4. Two of these car body side walls 4 are provided with entry doors 6. Another of these car body side walls 4 is designed as a car joining wall 8, through which a vehicle passenger can pass from the railroad car 2 into another railroad car that is coupled to the railroad car 2. For this purpose, the car joining wall 8 has a connecting door 10. For the sake of greater clarity, the other railroad car, which is coupled to the first-cited railroad car 2, is not illustrated in this figure.

The railroad car 2 also has a passenger space 12, in which a plurality of passenger seats 14 are arranged. In addition, the railroad car 2 has locomotive driver space 16, which is separated from the passenger space 12 by a separating wall 18.

The railroad car 2 is also equipped with a plurality of side wall inner panelings 20, which in each case conceal one of the car body side walls 4 and laterally delimit the passenger space 12 and/or the locomotive driver space 16.

The railroad car 2 also has a luggage rack 22, which is arranged in the passenger space 12. In addition, the railroad car 2 has two vestibule cabinets 24, each of which is arranged partially in different embarkation zones 26 of the railroad car 2.

Furthermore, the railroad car 2 is equipped with a control system 28. The control system 28 comprises a switchgear cabinet 30 in which a plurality of control elements 32 are arranged, these being communicatively connected to each other.

In addition, the control system 28 comprises a plurality of functional modules 34 which are arranged decentrally with respect to each other and are communicatively connected in each case via an electrical communication line 36 to the control elements 32 that are arranged in the switchgear cabinet 30. The functional modules 34 each have a housing with an externally accessible electrical interface (cf. FIG 4). Furthermore, in their respective housings the functional modules 34 have at least one printed circuit board onto which is soldered a relay unit that forms a control element of the control system 28 (cf. FIG. 5 and FIG. 6).

One of the functional modules 34 is arranged between the luggage rack 22 and one of the car body side walls 4. Two more of the functional modules 34 are each arranged in one of the vestibule cabinets 24. A further two of the functional modules 34 are placed next to the switchgear cabinet 30, in particular between the switchgear cabinet 30 and one of the car body side walls 4 or between the switchgear cabinet 30 and the separating wall 18. Another of the functional modules 34 is arranged between the car joining wall 8 and the side wall inner paneling 20 which conceals the car joining wall 8. Yet another of the functional modules 34 is arranged in the locomotive driver space 16 next to the separating wall 18.

Also shown in FIG. 1 is a sectional plane II-II, which is oriented perpendicularly relative to the longitudinal direction of the car 38. Also shown in FIG. 1 is a sectional plane III-III, which runs in a longitudinal direction of the car 38 through one of the embarkation zones 26 of the railroad car 2.

FIG. 2 shows a schematic section of the railroad car 2 along the sectional plane II-II from FIG. 1. In this figure, it is possible to identify two of the previously mentioned car body side walls 4 and side wall inner panelings 20, and the four passenger seats 14 arranged in the passenger space 12.

The railroad car 2 has a car body roof 40 and an inner ceiling 42 which represents an upper limit of the passenger space 12. The car body roof 40 has a cove 44 in the direction of the car body side walls 4 in each case. The railroad car 2 also has a car body floor 46 and a floorpan 48 which is arranged under the car body floor 46.

In addition, further functional modules 34 are arranged in FIG. 2. These further functional modules 34 are also communicatively connected via electrical connection lines to the control elements 32 arranged in the switchgear cabinet 30, though these communication lines are not illustrated in this figure.

One of the functional modules 34 is arranged under one of the passenger seats 14. Three more of the further functional modules 34 are arranged in an underfloor zone between the car body floor 46 and the floorpan 48. Two of these three functional modules 34 are arranged in particular in the region of a curve of the floorpan 48 and the third of these three functional modules 34 is fastened to the car body floor 46. Four more of the further functional modules 34 are arranged between the car body roof 40 and the inner ceiling 42. In particular, two of these four functional modules 34 are arranged under one of the coves 44 in each case. These two last-cited functional modules 34 are arranged obliquely relative to the horizontal.

FIG. 3 shows a schematic section of the railroad car 2 along the sectional plane III-III from FIG. 1. In the section illustrated, one of the embarkation zones 26 of the railroad car 2 is depicted. FIG. 3 shows inter alia a section of the car body roof 40, the inner ceiling 42, the car body floor 46 and the floorpan 48. One of the previously mentioned entry doors 6 is also shown.

Also depicted in FIG. 3 are a further three functional modules 34 of the control system 28. One of the further functional modules 34 is arranged between the car body roof 40 and the inner ceiling 42, in particular above the entry door 6, in the embarkation zone shown. The other two further functional modules 34 are arranged between the car body floor 46 and the floorpan 48 in the embarkation zone shown.

These three further functional modules 34 are likewise communicatively connected via an electrical communication line in each case to the control elements 32 arranged in the switchgear cabinet 30, though these communication lines are not illustrated in this figure.

FIG. 4 shows an exemplary embodiment of one of the previously mentioned functional modules 34 in a perspective view.

The functional module 34 has a cuboid housing 50 made of metal. Two fastening elements 52 are attached to the housing 50, in particular to its top side as shown in the drawing. The fastening elements 52 are used to fasten the functional module 34 to another component of the railroad car 2. In the present exemplary embodiment, the fastening elements 52 are angle brackets which are screwed onto the housing. The fastening elements 52 each have two plate-like sections 54 which are so oriented as to be perpendicular relative to each other. In this way, one of said sections 54 is attached to the housing 50 in each case.

The illustrated functional module 34 also has four externally accessible electrical interfaces 56, which are provided in each case for linking the functional module 34 via cables to one or more car-related elements. In the present exemplary embodiment, the interfaces 56 are designed as plug-type connectors. In addition, the interfaces 56 each have two threaded holes 58 by means of which a cable can be screwed onto the respective interface 56.

The present functional module 34 also has two passive heat sinks 60 comprising a plurality of cooling fins 62 in each case, said heat sinks 60 being attached to opposite sides of the housing 50.

The housing 50 is also equipped with a plurality of externally accessible blind rivet nuts 64. The blind rivet nuts 64 can be used to screw components such as e.g. the heat sinks 60 or the fastening elements 52 onto the housing 50. As an alternative or in addition to the blind rivet nuts 64, the housing 50 can have a plurality of threaded inserts.

FIG. 5 shows a section through the housing 50 of the functional module 34 from FIG. 4. In addition to two of the previously mentioned interfaces 56 and a plurality of the previously mentioned blind rivet nuts 64, two printed circuit boards 66 and a printed circuit board support unit 68 are visible in FIG. 2, the printed circuit boards 66 and the printed circuit board support unit 68 being arranged in the housing 50. The printed circuit board support unit 68 is used to hold the two printed circuit boards 66 in place in the housing 50.

A relay unit 70 which forms a control element of the control system 28 is soldered onto each of the two printed circuit boards 66. Furthermore, the two printed circuit boards 66 are electrically connected to the interfaces 56 of the functional module 34 by means of a back panel 72 which is arranged in the housing 50. For this purpose, the printed circuit boards 66 are plugged into slots of the back panel 72. In addition, the back panel 72 itself is electrically connected to the interfaces 56 of the functional module 34. In the present exemplary embodiment, by means of the back panel 72, each of the two printed circuit boards 66 is electrically connected respectively to two of the four electrical interfaces 56 of the functional module 34.

The remainder of the previously mentioned functional modules 34 can be designed in an identical manner to the functional module described in connection with FIG. 4 and FIG. 5. Alternatively, some or all of the other functional modules 34 may differ from each other or from the functional module 34 described in connection with FIG. 4 and FIG. 5 in respect of their number of interfaces 56, type of interfaces 56, number of heat sinks 60 and/or number of fastening elements 52.

Furthermore, the other functional modules 34 may differ from the functional module 34 described in connection with FIG. 4 and FIG. 5 in respect of those housing sides to which their fastening elements 52 and/or heat sinks 60 are attached.

By way of example, FIG. 6 shows a section through a housing 50 of another functional module 34 of the control system 28. The following description is limited essentially to the differences of the present functional module 34 compared with the functional module 34 from FIG. 5, to which reference is made in respect of features that remain the same. Essentially identical or corresponding elements are designated by the same reference signs in each case, and features that are not mentioned are transferred without being described again.

The functional module 34 illustrated in FIG. 6 has no back panel. Each of the electrical interfaces 56 of the functional module 34 is instead connected to a cable 74. The cables 74 have a plug-type connector 76 in each case. In addition, each of these cables 74 is connected with its plug-type connector 76 to one of the printed circuit boards 66 of the functional module 34, and therefore the printed circuit boards 66 of the functional module 34 are connected to the interfaces 56 by means of the cables 74.

Furthermore, the electrical interfaces 56 of the functional module 34 from FIG. 6 have a different type of plug-type connector to the electrical interfaces 56 of the functional module 34 from FIG. 5.

Although the invention is illustrated and described in detail with reference to the preferred exemplary embodiment, it is not limited by the example disclosed herein and other variations may be derived therefrom without departing from the scope of the invention.

1-15. (canceled)

16. A railroad car, comprising:
a control system including a plurality of functional modules;
said functional modules being disposed decentrally relative to each other; and
each of said functional modules having a respective housing with at least one externally accessible electrical interface.

17. The railroad car according to claim 16, wherein:
said interfaces of said functional modules are constructed as plug-type connectors; and
each of said functional modules includes:
at least one printed circuit board disposed in said housing of said respective functional module, said at least one printed circuit board being electrically connected to said interface of said respective functional module, and
a relay unit soldered onto said at least one printed circuit board of said respective functional module.

18. The railroad car according to claim 17, which further comprises a back panel or at least one cable electrically connecting said printed circuit board of said respective functional module to said interface of said respective functional module.

19. The railroad car according to claim 16, wherein:
said control system includes a switchgear cabinet and a plurality of control elements disposed in said switchgear cabinet;
said functional modules are disposed outside said switchgear cabinet; and
communication lines each communicatively connect a respective one of said functional modules to at least one of said control elements in said switchgear cabinet.

20. The railroad car according to claim 16, wherein said housings of said functional modules have identical dimensions.

21. The railroad car according to claim 16, wherein at least one of said functional modules has at least one heat sink being fastened to said housing of said at least one functional module, and said at least one heat sink includes a plurality of cooling fins.

22. The railroad car according to claim 16, wherein each of said functional modules is equipped with two respective fastening elements each having two respective plate-shaped sections oriented perpendicularly relative to each other.

23. The railroad car according to claim 16, which further comprises a plurality of passenger seats, at least one of said functional modules being disposed under at least one of said passenger seats.

24. The railroad car according to claim 16, which further comprises a car body roof and an inner ceiling, at least one of said functional modules being disposed between said car body roof and said inner ceiling.

25. The railroad car according to claim 24, wherein said car body roof has at least one cove, and said at least one functional module disposed between said inner ceiling and said car body roof is disposed under said at least one cove.

26. The railroad car according to claim 24, which further comprises an embarkation zone with an entry door, said at least one functional module disposed between said inner ceiling and said car body roof being disposed above said entry door in said embarkation zone.

27. The railroad car according to claim 16, which further comprises a car body floor and a floor pan, at least one of said functional modules being disposed between said car body floor and said floor pan.

28. The railroad car according to claim 16, which further comprises a car body side wall, and a side wall inner paneling, at least one of said functional modules being disposed between said car body side wall and said wall inner paneling.

29. The railroad car according to claim 28, wherein said car body side wall is a car joining wall.

30. The railroad car according to claim 16, which further comprises a luggage rack and a car body side wall, at least one of said functional modules being disposed between said luggage rack and said car body side wall.

31. The railroad car according to claim 16, which further comprises a switchgear cabinet and a car body side wall, at least one of said functional modules being disposed between said switchgear cabinet and said car body side wall.
